(19) United States
(12) Patent Application Publication
(10) Pub. No.: US 2014/0326489 A1
(43) Pub. Date: Nov. 6, 2014

(54) SYSTEMS AND METHODS FOR DECREASING STUB RESONANCE OF PLATING FOR CIRCUIT BOARDS

(71) Applicant: Dell Products L.P., Round Rock, TX (US)

(72) Inventors: Bhyrav M. Mutnury, Round Rock, TX (US); Sandor Farkas, Round Rock, TX (US)

(21) Appl. No.: 13/886,421

(22) Filed: May 3, 2013

(51) Int. Cl. H05K 1/02; H05K 3/32; H05K 3/10

(52) U.S. Cl. CPC H05K 1/0237; H05K 3/10; H05K 3/32; H05K 1/09
USPC 174/257; 29/846; 29/832; 174/261

(57) ABSTRACT

In accordance with embodiments of the present disclosure, a circuit board may include a stub corresponding to a portion of a trace running proximate to an edge of the circuit board, wherein the stub is configured to electrically couple to a plating bar for plating electrical paths of the circuit board with a conductive metal and a termination pad electrically coupled to the stub and configured to electrically couple to a termination resistor for resistively terminating the stub.

### TECHNICAL FIELD

The present disclosure relates in general to information handling systems, and more particularly to a system and method for decreasing stub resonance of gold plating for circuit boards.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

An information handling system may include one or more circuit boards operable to mechanically support and electrically couple electronic components making up the information handling system. For example, circuit boards may be used as part of motherboards, memories, storage devices, storage device controllers, peripherals, peripheral cards, network interface cards, and/or other electronic components. As is known in the art, a circuit board may comprise a plurality of conductive layers separated and supported by layers of insulating material laminated together, with conductive traces disposed on and/or in any of such conductive layers.

During fabrication of a circuit board, some or all of the traces, vias, pads, and/or other electrically conductive elements of the circuit board may be plated with hard gold, in a process known as plating. Plating ensures that the circuit board can make a solid electrical connection and strengthens the electrical integrity of the circuit board. Usually, all features of the PCB requiring plating are plated at the same time.

The typical plating process involves shorting all the contact pads by connecting them to small traces, which extend off the front edge of the circuit board. The small traces then connect to a plating bar and a voltage is applied. By connecting all of the traces to a plating bar, all of the signal paths requiring plating in the circuit board form a single conductive path. By applying a voltage, the resulting current electrically plates the gold on to the contact pads. In other words, all necessary signal paths are plated with hard gold at the same time. After the plating process is complete, the traces used to plate the appropriate portions of the circuit board are cut at the front edge of the circuit board, thus eliminating the short between the contact pads. One of the problems with this process is that small traces that extend from the contact pads to the front edge of the circuit board remain on the circuit board.

This problem is illustrated in FIGS. 1A and 1B where portions of the traces used to plate the contact pads, known as stubs, remain after the circuit board has been routed to a final form factor. In FIGS. 1A and 1B, contact pads 102 provide electrical access to the signal or conductive paths of circuit board 100. As previously described during the plating process, traces 104 are formed and electrically coupled to a plating bar 106 as shown in FIG. 1A. After plating, traces 104 are cut at cut line 108 at a front edge 103 of circuit board 100, leaving stubs 105 remaining of traces 104. Note that FIGS. 1A and 1B illustrate contact pads 102 of circuit board 100, but it is understood that the other conductive paths that are electrically coupled to the contact pads may also be plated.

However, the stubs 105 remaining after plating using plating bar 106 may lead to poor signal integrity of signals routed through circuit board 100. For example, a stub 105 may act as an antenna, and thus may resonate at frequencies (and harmonics thereof) for which the length of a stub 105 is equal to one-quarter of the wavelength of such frequencies. As transmission frequencies used in circuit boards increase, signals operating at such frequencies may be affected by such resonances, resulting in decreased signal integrity. In addition, a stub 105 may reflect signals, wherein such signals may be delayed from an original signal and reflect back into such signal, thus effectively acting as a comb filter, and leading to poor signal integrity.

### SUMMARY

In accordance with the teachings of the present disclosure, the disadvantages and problems associated with resonance in printed circuit board traces have been reduced or eliminated.

In accordance with embodiments of the present disclosure, a circuit board may include a stub corresponding to a portion of a trace running proximate to an edge of the circuit board, wherein the stub is configured to electrically couple to a plating bar for plating electrical paths of the circuit board with a conductive metal and a termination pad electrically coupled to the stub and configured to electrically couple to a termination resistor for resistively terminating the stub.

In accordance with these and other embodiments of the present disclosure, a method may include forming a trace on a circuit board including a stub, the stub corresponding to a portion of the trace running proximate to an edge of the circuit board, wherein the stub is configured to electrically couple to a plating bar for plating electrical paths of the circuit board with a conductive metal. The method may also include forming a termination pad electrically coupled to the stub and configured to electrically couple to a termination resistor for resistively terminating the stub.

In accordance with these and other embodiments of the present disclosure, an information handling system may include a circuit board and at least one information handling resource other than the circuit board. The circuit board may comprise a stub corresponding to a portion of a trace running proximate to an edge of the circuit board, wherein the stub is configured to electrically couple to a plating bar for plating electrical paths of the circuit board with a conductive metal and a termination pad electrically coupled to the stub and configured to electrically couple to a termination resistor for resistively terminating the stub.

Technical advantages of the present disclosure will be apparent to those of ordinary skill in the art in view of the following specification, claims, and drawings.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIGS. 1A and 1B each illustrate a plan view of selected components of a printed circuit board, as is known in the art;

FIGS. 2A and 2B each illustrate a plan view of selected components of a printed circuit board, in accordance with embodiments of the present disclosure;

FIG. 3 illustrates a flow chart of an example method for determining a termination resistor resistance, in accordance with embodiments of the present disclosure; and

FIG. 4 illustrates a block diagram of an example information handling system, in accordance with certain embodiments of the present disclosure.

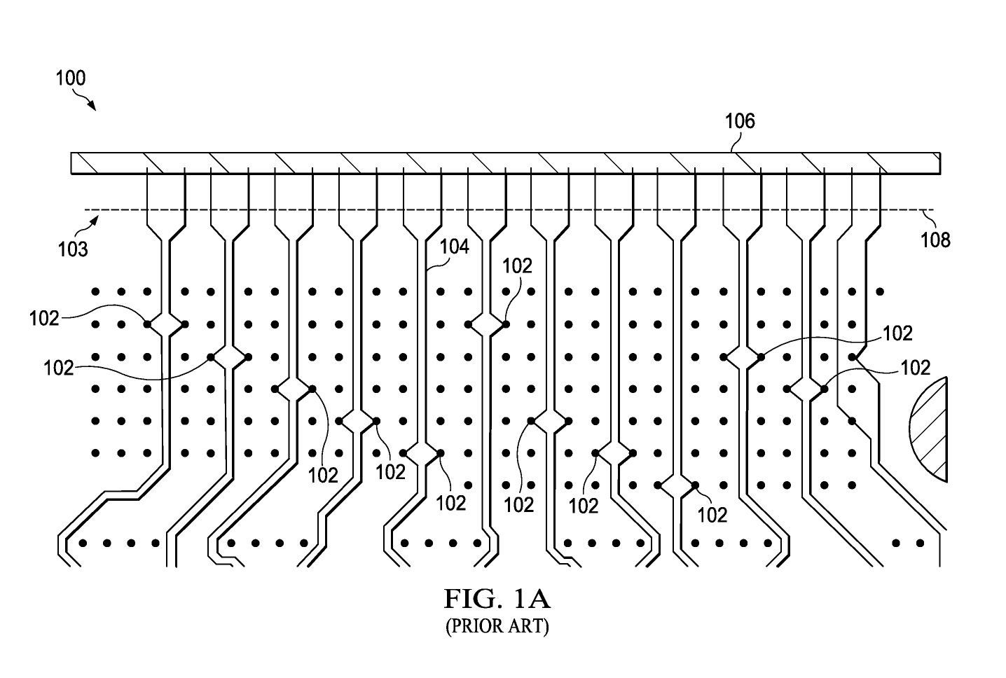

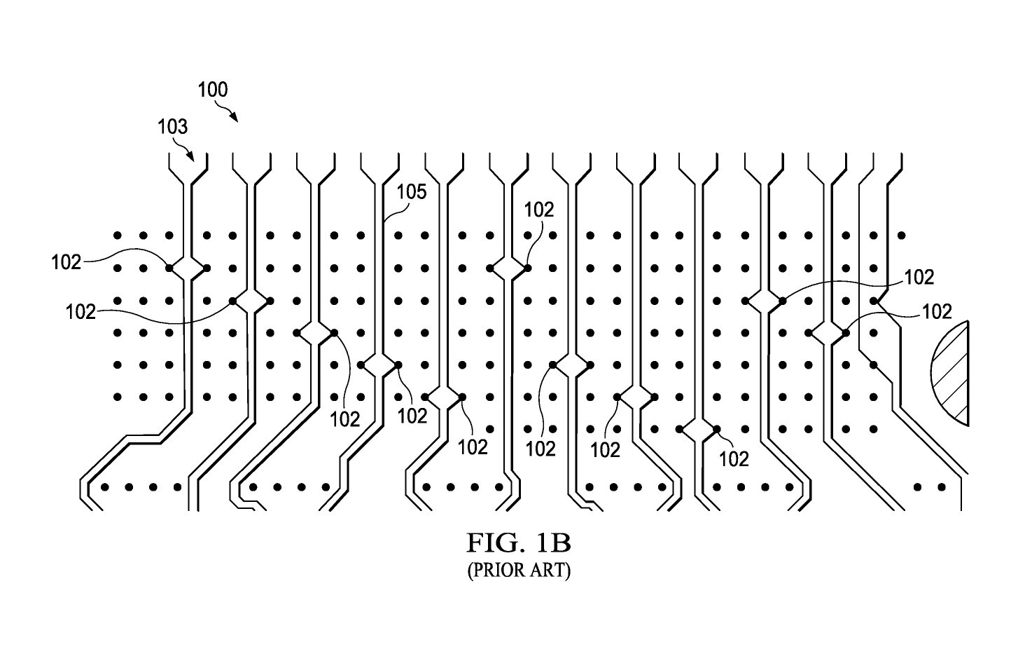

### DETAILED DESCRIPTION

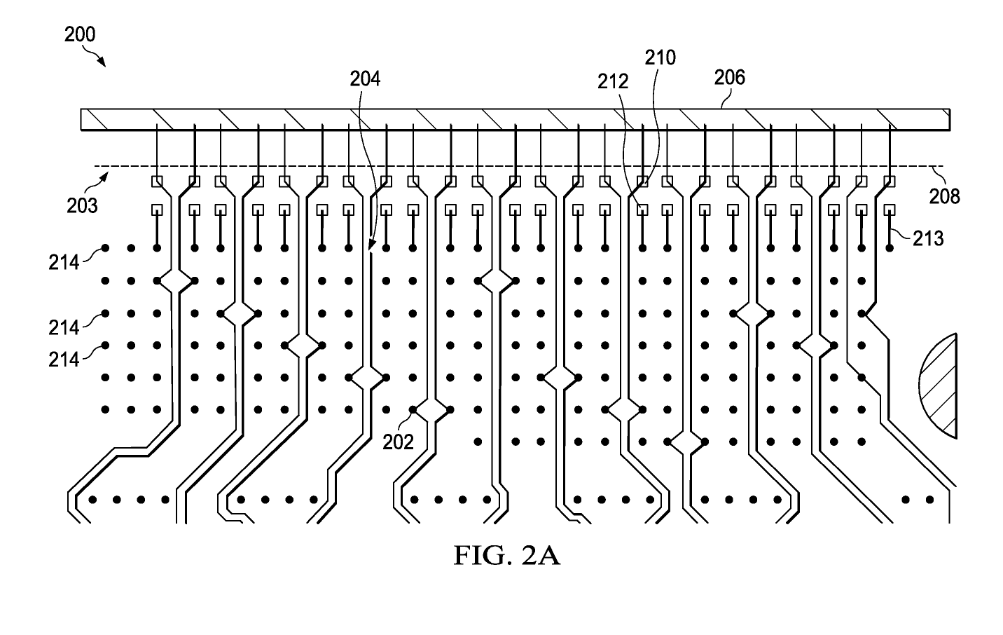

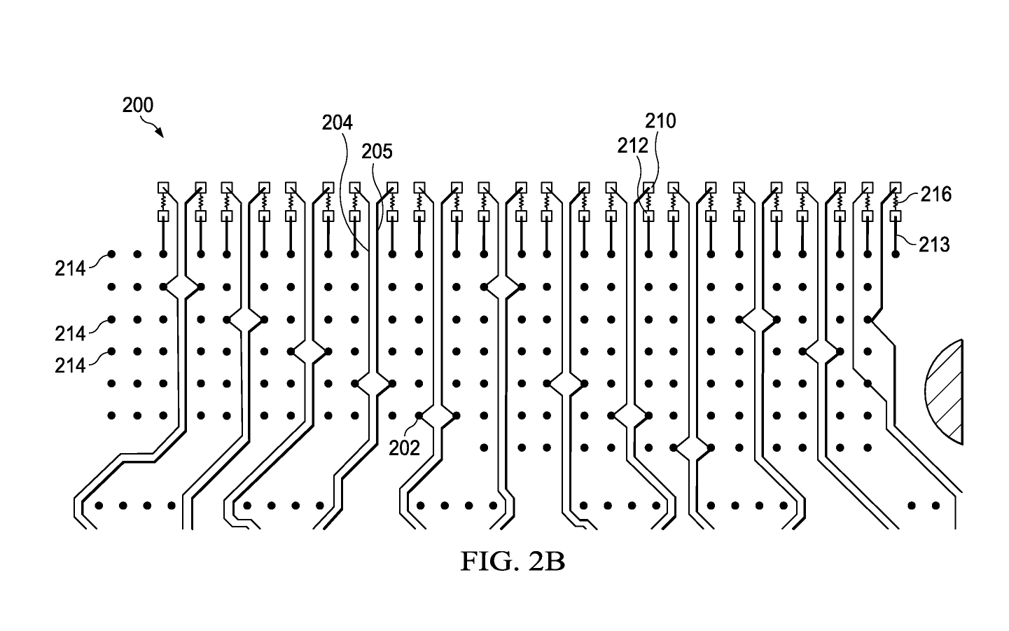

Preferred embodiments and their advantages are best understood by reference to FIGS. 2A through 4, wherein like numbers are used to indicate like and corresponding parts.

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems, buses, memories, I/O devices and/or interfaces, storage resources, network interfaces, motherboards, and/or any other components and/or elements of an information handling system.

As discussed above, an information handling system may include one or more circuit boards operable to mechanically support and electrically connect electronic components making up the information handling system (e.g., packaged integrated circuits). Circuit boards may be used as part of motherboards, memories, storage devices, storage device controllers, peripherals, peripheral cards, network interface cards, and/or other electronic components. As used herein, the term “circuit board” includes printed circuit boards (PCBs), printed wiring boards (PWBs), etched wiring boards, and/or any other board or similar physical structure operable to mechanically support and electrically couple electronic components.

FIGS. 2A and 2B each illustrate an elevation view of selected components of a circuit board 200, in accordance with embodiments of the present disclosure. FIG. 2A depicts circuit board 200 with a plating bar 206 coupled thereto for plating during the fabrication process for circuit board 200, while FIG. 2B depicts circuit board 200 in a finished state.

As shown in FIGS. 2A and 2B, circuit board 200 may comprise contact pads 202 and termination pads 210 and 212, traces 204, ground connection traces 213, vias 214 and/or other electrically conductive components for providing electrical access to signal and/or conductive paths of circuit board 200. A pad (whether a contact pad 202 or termination pad 210, 212) may comprise a substantially electrically conductive material and may be formed on a surface of circuit board 200 or in a layer of circuit board 200 not visible from the surface thereof, and configured to electrically couple electrically conductive paths of circuit board 200 to other components (e.g., integrated circuit packages, resistors, capacitors, inductors, transistors, etc.) mounted to or otherwise mechanically coupled to circuit board 200. Each trace 204 and ground connection trace 213 may comprise a substantially electrically conductive material and may be formed on a surface of circuit board 200, or in a layer of circuit board 200 not visible from the surface thereof, and configured to provide an electrically conductive path between various elements of circuit board 200. A via 214 may comprise a substantially electrically conductive material and may be formed such that via 214 may electrically couple together traces 204 on different layers of circuit board 200, thus allowing signals to propagate between layers of circuit board 200. In some embodiments, via 214 may be substantially cylindrical in shape.

During fabrication of circuit board 200, and prior to plating, each trace 204 may be coupled to a termination pad 210 proximate to front edge 203 of circuit board 200. In addition, one or more termination pads 212 may be formed proximate to termination pads 210, and may be coupled to a ground plane (not explicitly shown) of circuit board 200 via a ground connection trace 213, a via 214, and/or other conductive paths of circuit board 200. In some embodiments, each single termination pad 212 may be formed proximate to an associated single termination pad 210.

To plate pads 202, traces 204, vias 214, and/or other electrically conductive components of circuit board 200, traces 204 may be electrically coupled to a plating bar 206 proximate to front edge 203 of circuit board 200 as shown in FIG. 2A, which creates an electrical short circuit among conductive paths of circuit board 200 to be plated. In addition, although not shown in FIGS. 2A and 2B, one or more traces 204 may electrically couple plating bar 206 to one or more ground planes of circuit board 200 in order to plate all pads, and not just signal pads 202. By applying a voltage to plating bar 206, the resulting current may plate gold onto the various conductive paths. After plating is complete, traces 204 extending to plating bar 206 are cut at trim line 208, thus removing plating bar 206 and eliminating the short circuit among the various conductive paths, and leaving behind stubs 205 of traces 204, as shown in FIG. 2B. Furthermore, after plating is complete, a termination resistor 216 may be coupled to each stub 205, as depicted in FIG. 2B. In the embodiments represented by FIG. 2B, a termination resistor 216 may be coupled at one terminal to a termination pad 210 and at its other terminal to a termination pad 212, thus electrically coupling each termination resistor 216 between a corresponding stub 205 and a ground plane. In some embodiments, each single termination resistor 216 may be electrically coupled to an associated single termination pad 212. A termination resistor 216 may comprise any system, device, or apparatus having a substantial electrical resistance (e.g., greater than or equal to five ohms).

Accordingly, each stub 205 may be terminated with an associated termination resistor 216. In some embodiments, individual resistances of the individual termination resistors 216 may be in accordance with method 300 or another similar method.

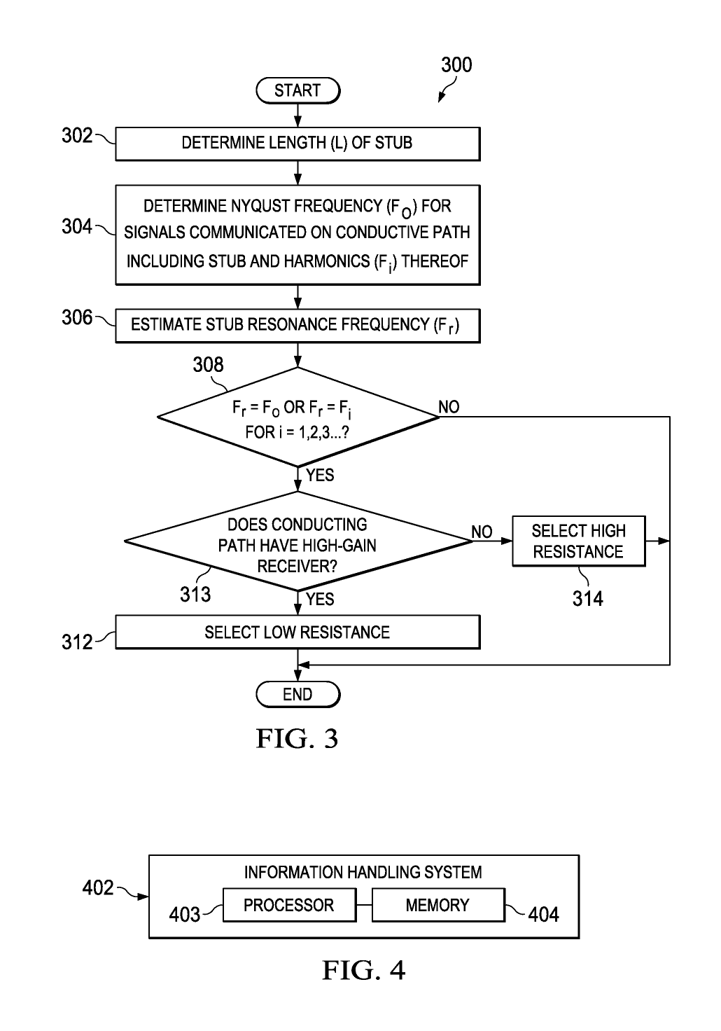

FIG. 3 illustrates a flow chart of an example method 300 for determining a termination resistor resistance, in accordance with embodiments of the present disclosure. According to some embodiments, method 300 preferably begins at step 302. As noted above, teachings of the present disclosure may be implemented in a variety of configurations of circuit board 200. As such, the preferred initialization point for method 300 and the order of the steps comprising method 300 may depend on the implementation chosen.

At step 302, a length (L) of a stub (e.g., stub 205) may be determined. In addition, at step 304, a Nyquist frequency (F₀) may be calculated for the bandwidth of signals to be transmitted on a conductive path to which the stub is electrically coupled, in addition to harmonics (Fᵢ) of the Nyquist frequency, which may be integer multiples of the Nyquist frequency.

At step 306, based on the length L of the stub, a resonance frequency (Fᵣ) of the stub may be estimated. For example, such estimate may be made in accordance with the equation Fᵣ=1/(4Ltₚᵣₒₚ), where tₚᵣₒₚ equals the propagation time per unit length of a signal through the stub.

At step 308, a determination may be made whether the resonance frequency Fᵣ is approximately equal (e.g., within a pre-defined tolerance of) the Nyquist frequency F₀ or any of the harmonic frequencies Fᵢ, thus indicating potential interference of signals by the via stub resonance. If the resonance frequency is approximately equal to the Nyquist frequency or any of the harmonic frequencies, method 300 may proceed to step 310. Otherwise, method 300 may end.

At step 310, a determination may be made whether the conductive path to which the stub is electrically coupled has a high-gain receiver (e.g., a receiver with a gain above a particular pre-determined threshold). If the conductive path to which the stub is electrically coupled has a high-gain receiver, method 300 may proceed to step 312. Otherwise method 300 may proceed to step 314.

At step 312, in response to a determination that the conductive path to which the stub is electrically coupled has a high-gain receiver, a low resistance (e.g., less than or equal to 50 ohms) may be selected to terminate the stub. After completion of step 312, method 300 may end.

At step 314, in response to a determination that the conductive path to which the stub is not electrically coupled has a high-gain receiver, a high resistance significantly greater than the low resistance (e.g., between 50 ohms and 150 ohms) may be selected to terminate the stub. After completion of step 314, method 300 may end.

Although FIG. 3 discloses a particular number of steps to be taken with respect to method 300, method 300 may be executed with greater or lesser steps than those depicted in FIG. 3. In addition, although FIG. 3 discloses a certain order of steps to be taken with respect to method 300, the steps comprising method 300 may be completed in any suitable order.

Method 300 may be implemented using any system operable to implement method 300. In certain embodiments, method 300 may be implemented partially or fully in software and/or firmware embodied in computer-readable media. In these and other embodiments, method 300 may be performed by an information handling system, for example information handling system 400 depicted in FIG. 4.

FIG. 4 illustrates a block diagram of an example information handling system 402, in accordance with certain embodiments of the present disclosure. As depicted in FIG. 4, information handling system 402 may include a processor 403 and a memory 404 communicatively coupled to processor 403.

Processor 403 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 403 may interpret and/or execute program instructions and/or process data stored in memory 404 and/or another information handling resource of information handling system 402.

Memory 404 may be communicatively coupled to processor 403 and may include any system, device, or apparatus configured to retain program instructions and/or data for a period of time (e.g., computer-readable media). Memory 404 may include RAM, EEPROM, a PCMCIA card, flash memory, magnetic storage, opto-magnetic storage, or any suitable selection and/or array of volatile or non-volatile memory that retains data after power to information handling system 402 is turned off. In some embodiments, memory 404 may have stored thereon a program of instructions that when read and executed by processor 403, carries out method 300 described above.

In addition to processor 403 and memory 404, information handling system 402 may include one or more other information handling resources.

Although the present disclosure has been described in detail, it should be understood that various changes, substitutions, and alterations can be made hereto without departing from the spirit and the scope of the disclosure as defined by the appended claims.

What is claimed is:

1. A circuit board, comprising:
a stub corresponding to a portion of a trace running proximate to an edge of the circuit board, wherein the stub is configured to electrically couple to a plating bar for plating electrical paths of the circuit board with a conductive metal; and
a termination pad electrically coupled to the stub and configured to electrically couple to a termination resistor for resistively terminating the stub.

2. The circuit board of claim 1, further comprising the termination resistor.

3. The circuit board of claim 2, wherein the termination resistor is electrically coupled between the termination pad and a ground plane of the circuit board.

4. The circuit board of claim 2, wherein a resistance of the termination resistor is selected based on a gain of a receiver to which the stub is to be electrically coupled.

5. The circuit board of claim 1, wherein the termination resistor is electrically coupled to the termination pad if a resonance frequency of the stub is approximately equal to a Nyquist frequency or one or more harmonic frequencies of the Nyquist frequency of signals communicated on a conductive path comprising the stub.

6. The circuit board of claim 5, wherein the resonance frequency is based on a length of the stub.

7. The circuit board of claim 1, further comprising a second termination pad formed proximate to the termination pad such that the termination resistor may be electrically coupled between the termination pad and the second termination pad.

8. The circuit board of claim 7, wherein the second termination pad is electrically coupled to a ground plane of the circuit board.

9. The circuit board of claim 1, wherein the conductive metal is gold.

10. A method, comprising:
forming a trace on a circuit board including a stub, the stub corresponding to a portion of the trace running proximate to an edge of the circuit board, wherein the stub is configured to electrically couple to a plating bar for plating electrical paths of the circuit board with a conductive metal; and
forming a termination pad electrically coupled to the stub and configured to electrically couple to a termination resistor for resistively terminating the stub.

11. The method of claim 10, further comprising electrically coupling the termination resistor to the termination pad.

12. The method of claim 11, further comprising selecting a resistance of the termination resistor based on a communication rate of a receiver to which the stub is to be electrically coupled.

13. The method of claim 10, further comprising electrically coupling the termination resistor between the termination pad and a ground plane of the circuit board.

14. The method of claim 10, further comprising determining whether to couple the termination resistor to the termination pad based on the length of the stub.

15. The method of claim 14, wherein determining whether to couple the termination resistor to the termination pad based on the length of the stub comprises:
determining a length of the stub;
determining a Nyquist frequency of signals communicated on a conductive path comprising the stub and one or more harmonic frequencies thereof;
estimating a resonance frequency of the stub based on the length; and
in response to determining that the resonance frequency is approximately equal to the Nyquist frequency or one of the one or more harmonic frequencies, coupling the termination resistor to the termination pad.

16. The method of claim 10, further comprising forming a second termination pad proximate to the termination pad such that the termination resistor may be electrically coupled between the termination pad and the second termination pad.

17. The method of claim 16, further comprising electrically coupling the second termination pad to a ground plane of the circuit board.

18. The method of claim 10, wherein the conductive metal is gold.

19. An information handling system comprising:
a circuit board, comprising:
a stub corresponding to a portion of a trace running proximate to an edge of the circuit board, wherein the stub is configured to electrically couple to a plating bar for plating electrical paths of the circuit board with a conductive metal; and
a termination pad electrically coupled to the stub and configured to electrically couple to a termination resistor for resistively terminating the stub.
at least one information handling resource other than the circuit board.

20. The information handling system of claim 19, wherein the circuit board further comprises the termination resistor.
